(19) United States
(12) Patent Application Publication
(10) Pub. No.: US 2014/0238618 A1
(43) Pub. Date: Aug. 28, 2014

(54) DIE EJECTOR AND DIE SEPARATION METHOD

(71) Applicant: SAMSUNG ELECTRONICS CO., LTD., Suwon-si (KR)

(72) Inventors: Yisung HWANG, Asan-si (KR); Sunghee CHO, Cheonan-si (KR); Byungwook KIM, Asan-si (KR); Chulmin KIM, Cheonan-si (KR); Yongdae HA, Asan-si (KR)

(73) Assignee: SAMSUNG ELECTRONICS CO., LTD., Suwon-si (KR)

(21) Appl. No.: 14/193,047

(22) Filed: Feb. 28, 2014

(30) Foreign Application Priority Data
Feb. 28, 2013 (KR) 10-2013-0022312

(51) Int. Cl. H01L 21/67

(52) U.S. Cl. CPC H01L 21/67005
USPC 156/750

(57) ABSTRACT

A die ejector includes a supporting unit configured to support a bottom surface of a film on which a die may be attached. The supporting unit may have a hole formed at a center thereof. The die ejector may further include a ring-shaped elevating unit in the hole and configured to move along a vertical direction, a driving unit connected to the elevating unit and configured to move the elevating unit along the vertical direction, and a pressure controlling unit connected to the hole and configured to control a pressure of the hole.

### CROSS-REFERENCE TO RELATED APPLICATIONS

This U.S. non-provisional patent application claims priority under 35 U.S.C. §119 from Korean Patent Application No. 10-2013-0022312, filed on Feb. 28, 2013 in the Korean Intellectual Property Office, and all the benefits accruing therefrom, the contents of which are herein incorporated by reference in their entirety.

### BACKGROUND

Exemplary embodiments of the inventive concept are directed to a die ejector and a die separation method.

A semiconductor packaging process may include a sawing step that cuts a wafer into a plurality of semiconductor chips or dies, a die-bonding step that bonds each die onto a substrate, a wire-bonding step that connects the die electrically to the substrate using wires, a molding step that encapsulates the structure including the die and wires with a molding layer, and a step of forming outer connection terminals on ball pads of the substrate.

A film may be attached to a bottom surface of the wafer to prevent the dies from being unintentionally detached in the sawing step. A die ejector may be used to separate each of the dies from the film. However, as the die becomes thinner and thinner, there is an increased risk of the die breaking, e.g., in the step of being separated from the film.

### SUMMARY

Exemplary embodiments of the inventive concept provide a die ejector capable of safely separating a die from a film and a die separation method using the same.

According to exemplary embodiments of the inventive concepts, a die ejector may include a supporting unit configured to support a bottom surface of a film on which a die may be attached, where the supporting unit has a hole disposed at a center thereof, an elevating unit in the hole and configured to move along a vertical direction, where the elevating unit has a ring-shaped structure, a driving unit connected to the elevating unit and configures to move the elevating unit along the vertical direction, and a pressure controlling unit connected to the hole and configured to control a pressure of the hole.

According to exemplary embodiments of the inventive concepts, a method of separating a die from a film may include forming an inhalation pressure in a hole in a center of a ring-shaped supporting unit using a pressure controlling unit connected to the hole, where the film is supported by the supporting unit and an elevating unit disposed in the hole and configured to move along a vertical direction.

According to exemplary embodiments of the inventive concepts, a die ejector may include a supporting unit configured to support a bottom surface of a film on which a die is attached, wherein the supporting unit has a hole disposed at a center thereof, a ring shaped elevating unit contained within in the hole and configured to move along a vertical direction, and a pressure controlling unit connected to the hole. The pressure controlling unit is configured to apply an inhalation pressure to the hole to separate the film from the die, and to supply gas into the hole to apply an injection pressure to the hole after the film is separated from the die.

### BRIEF DESCRIPTION OF THE DRAWINGS

FIG. 1 is a plan view of a die bonding apparatus.

FIG. 2 is a side sectional view of the wafer holder of FIG. 1.

FIG. 3 is a plan view of a die ejector according to exemplary embodiments of the inventive concept.

FIG. 4 is a side sectional view of a die ejector of FIG. 3.

FIG. 5 is a schematic diagram of a pressure controlling unit of the die ejector of FIG. 3.

FIG. 6 is a block diagram that illustrates the functions of a control unit.

FIG. 7 is a schematic diagram that illustrates how a die is separated from a film by elevating a position of an elevating unit.

FIGS. 8 through 10 are schematic diagrams that illustrate a hole to which an inhalation pressure is applied.

FIG. 11 is a schematic diagram that illustrates a hole to which an injection pressure is applied.

FIG. 12 is a plan view of a die ejector according to other exemplary embodiments of the inventive concept.

FIG. 13 is a side sectional view of the die ejector of FIG. 12.

FIG. 14 is a schematic diagram that illustrates how a die is separated from a film by the die ejector of FIG. 12.

FIG. 15 is a plan view of a die ejector according to still other exemplary embodiments of the inventive concept.

FIG. 16 is a side sectional view of the die ejector of FIG. 15.

### DETAILED DESCRIPTION OF EXEMPLARY EMBODIMENTS

Exemplary embodiments of the inventive concepts will now be described more fully with reference to the accompanying drawings, in which exemplary embodiments are shown. Exemplary embodiments of the inventive concepts may, however, be embodied in many different forms and should not be construed as being limited to the embodiments set forth herein. Like reference numerals in the drawings may denote like elements, and thus their description will be omitted.

It will be understood that when an element is referred to as being “connected” or “coupled” to another element, it can be directly connected or coupled to the other element or intervening elements may be present.

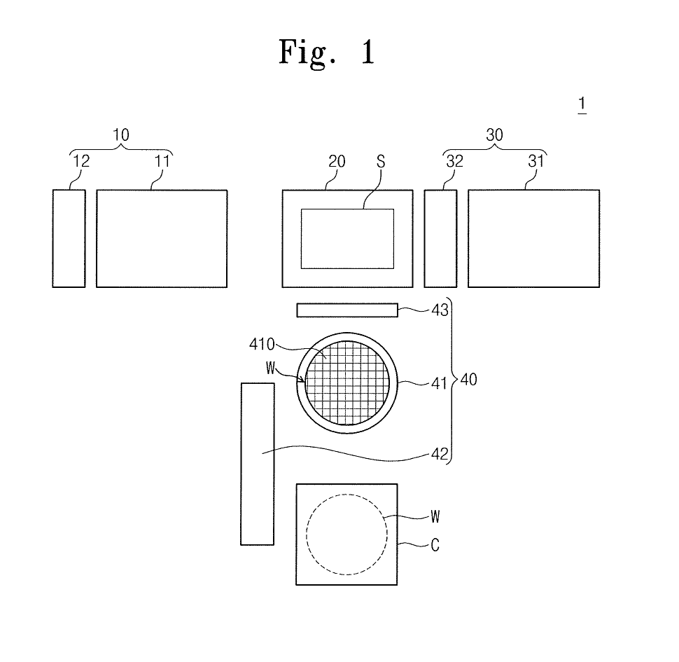

FIG. 1 is a plan view of a die bonding apparatus.

Referring to FIG. 1, a die bonding apparatus 1 may include a loading unit 10, a working stage 20, an unloading unit 30, and a die-supplying unit 40.

The loading unit 10 may be configured to load a substrate S onto the working stage 20. The loading unit 10 may include a supplying container 11 and a loader 12. The supplying container 11 may be configured to contain the substrates S to which semiconductor chips are attached. The loader 12 may sequentially load the substrates S from the supplying container 11 onto the working stage 20. The substrate S contained in the supplying container 11 may be a printed circuit board (PCB) or a lead frame.

The working stage 20 may be disposed adjacent to the loading unit 10. The working stage 20 may provide a working region where the substrate S to be loaded from the loading unit 10 will be positioned. A die 410 may be attached onto the substrate S on the working region.

The unloading unit 30 may be configured to unload the substrate S with the attached die 410 from the working stage 20. The unloading unit 30 may be located adjacent to the working stage 20. For example, the unloading unit 30 may be disposed opposite to the loading unit 10. Alternatively, the unloading unit 30 and the loading unit 10 may be disposed side by side near the working stage 20. The unloading unit 30 may include a receiving container 31 and an unloader 32. The receiving container 31 may be configured to contain the substrates S with the attached die 410. The unloader 32 may be configured to unload the substrate S with the attached 410 from the working stage 20 and load it into the receiving container 31.

The die-supplying unit 40 may be configured to separate the die 410 from a wafer W and attach it to the substrate S. The die-supplying unit 40 may be disposed adjacent to the working stage 20. The die-supplying unit 40 may include a wafer holder 41, a delivering robot 42, and a bonding head 43.

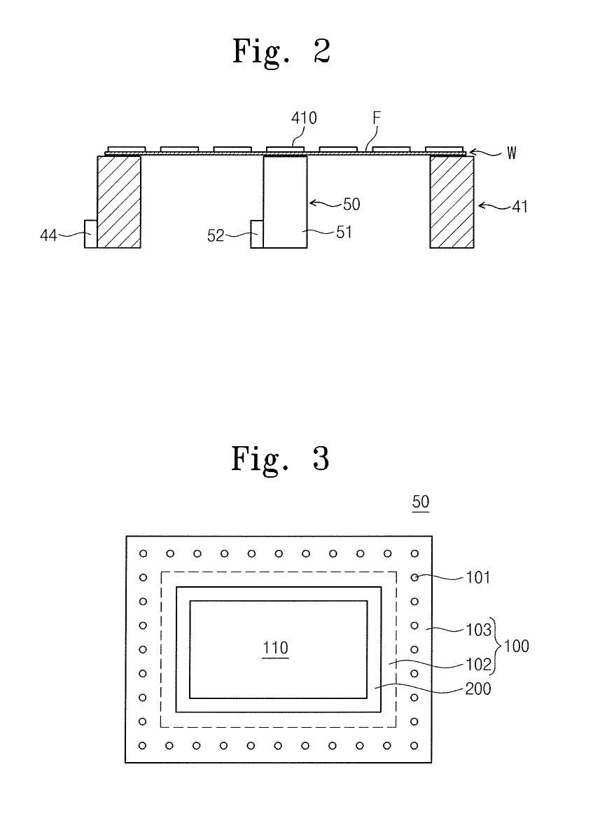

FIG. 2 is a side sectional view of the wafer holder 41 of FIG. 1.

Referring to FIG. 2, the wafer holder 41 may support the wafer W while separating the die 410 from the wafer W. A cassette C may be disposed adjacent to the wafer holder 41. For example, the cassette C may be disposed opposite to the working stage 20. The cassette C may be moved by an operator or a delivering unit. For example, the delivering unit may be an overhead hoist transport (OHT) or an automatic guided vehicle. The wafer W may be contained on the cassette C. In exemplary embodiments, at least one of a fabrication, electrical die sorting, or back grinding processes may have been performed on the wafer W. A film F may be attached to a bottom surface of the wafer W, and a sawing process may be performed on the wafer W with the film F. Accordingly, the dies 410 may be attached on the film F. The top surface of the film F may be treated by ultraviolet light, which enables an easy detachment of the die 410 from the film F in a subsequent process. In addition, a wafer ring may be provided along an edge portion of the wafer W. The wafer holder 41 may be configured to support the wafer W and pull the wafer ring outward. Accordingly, the film F may expand, which may enable separating the die 410 from the film F with ease.

The delivering robot 42 may be located adjacent to the wafer holder 41 and the cassette C. The delivering robot 42 may pull the wafer W out from the cassette C and dispose it on the wafer holder 41.

A die ejector 50 may be provided in the wafer holder 41. The die ejector 50 may be configured to separate the die 410 from the film F. The bonding head 43 may pick-up the separated die 410 and attach it to the substrate S loaded on the working stage 20. For example, the die 410 pick-up may be performed using a vacuum suction technique. The die 410 may be attached to the substrate S using adhesives. The adhesives may be a conductive adhesive, such as Ag-epoxy or Ag-glass.

The adhesives may be coated on a top surface of the substrate S provided on the working stage 20. Thereafter, the bonding head 43 may be operated to dispose the die 410 on the top surface of the substrate S. In exemplary embodiments, the bonding head 43 may apply a predetermined pressure to a top surface of the die 410 to attach firmly the die 410. Furthermore, the adhesives may be provided on a bottom surface of the die 410 facing the substrate S. In other words, the adhesives may be provided between the bottom surface of the die 410 and the top surface of the film F. The adhesives may separate from the film F when the die 410 is detached.

A first delivering unit 44 may be provided in the wafer holder 41. The first delivering unit 44 may move the wafer holder 41 along a horizontal direction relative to the die ejector 50. Accordingly, if a die 410 is separated by the die ejector 50 and moved to the bonding head 43, the wafer holder 41 may be moved so that another die 410 is disposed on the die ejector 50.

The die ejector 50 may include a housing 51 and a second delivering unit 52. The housing 51 may define an overall shape of the die ejector 50. The second delivering unit 52 may move the housing 51 along the horizontal direction relative to the wafer holder 41. Accordingly, if a die 410 is separated by the die ejector 50 and moved to the bonding head 43, the die ejector 50 may move so that another die 410 is disposed on the die ejector 50. The first and second delivering units 44 and 52 may be provided in conjunction with each other to move the wafer holder 41 and the die ejector 50 at the same time. Further, one of the first and second delivering units 44 and 52 may be omitted to move one of the die ejector 50 and the wafer holder 41.

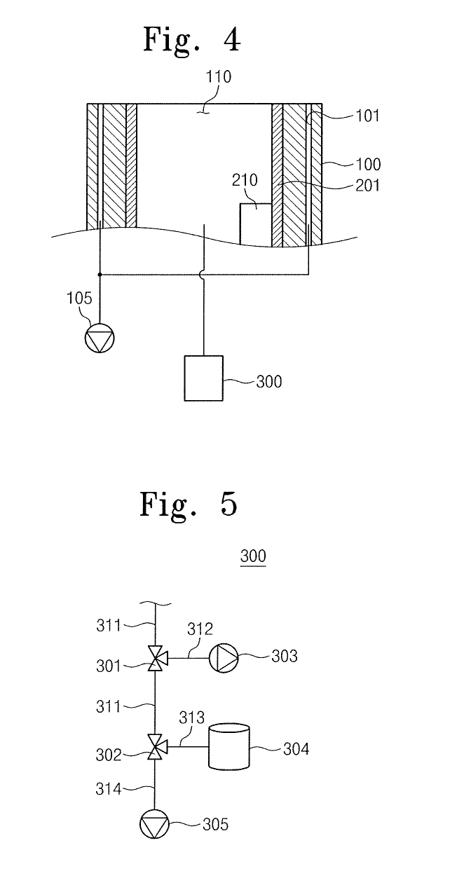

FIG. 3 is a plan view of a die ejector according to exemplary embodiments of the inventive concept, and FIG. 4 is a side sectional view of a die ejector of FIG. 3.

Referring to FIGS. 3 and 4, the die ejector 50 may include a supporting unit 100 and an elevating unit 200.

A top surface of the housing 51 may serve as the supporting unit 100. Alternatively, the supporting unit 100 may be independently disposed on the top surface of the housing 51. In a plan view, the supporting unit 100 may have a circular, an elliptical, or a polygonal shape. The supporting unit 100 may have an area that is larger than that of each dies 410.

The supporting unit 100 may be provided with a hole 110 located at a center thereof. For example, the supporting unit 100 may have a ring-like shape. The hole 110 may have a circular, an elliptical, or a polygonal shape. In exemplary embodiments, the hole 110 may have a shape resembling or corresponding to that of the die 410. For example, the hole 110 may have a rectangular or square shape. In a plan view, an area of the hole 110 may be smaller than that of the die 410, and thus, if the die 410 is positioned on a center of the die ejector 50, a central portion of the die 410 may overlap with the hole 110 and an edge portion of the die 410 may overlap with the supporting unit 100.

The supporting unit 100 may be formed to have fixing holes 101. The fixing holes 101 may allow the film F to remain fastened to the supporting unit 100 when the die 410 is separated from the film F. In exemplary embodiments, a top surface of the supporting unit 100 may be divided into a supporting part 102 and a fixing part 103. The supporting part 102 may be an inner portion of the top surface of the supporting unit 100 located adjacent to the hole 110. The fixing part 103 may be an outer portion located outside the supporting part 102. The supporting part 102 may have an area corresponding to that of the die 410. The fixing holes 101 may be provided along or around the fixing part 103 or the supporting part 102. The fixing holes 101 may be connected to a depressurizing unit 105. The depressurizing unit 105 may be configured to apply a vacuum pressure to the fixing holes 101. In addition, the fixing holes 101 may be connected to a depressurizing unit 303, which may constitute a pressure controlling unit 300 to be described below.

The elevating unit 200 may be disposed in the hole 110 in the central portion of the supporting unit 100. In a plan view, the elevating unit 200 may be have a circular ring, an elliptical ring, or a polygonal ring shape. An outer side surface of the elevating unit 200 may have a shape corresponding to that of the hole 110. The elevating unit 200 may have an area that is smaller than that of the die 410. A side surface of the elevating unit 200 may be adjacent to an inner side surface of the supporting unit 100. Furthermore, the outer side surface of the elevating unit 200 may be contained within the hole 110, and thus, the outer side surface of the elevating unit 200 may be spaced apart from the inner side surface of the supporting unit 100 by a specific distance. The elevating unit 200 may include an elevation axis 201 that extends downward from the ring-shaped upper portion. The elevation axis 201 may be connected to a driving unit 210. The driving unit 210 may reciprocate the elevating unit 200 between standby and separation positions using the elevation axis 201. At the standby position, a top surface of the elevating unit 200 may be substantially even with or lower than that of the supporting unit 100. At the separation position, the top surface of the elevating unit 200 may be higher than that of the supporting unit 100. The elevating unit 200 may move higher than the supporting unit 100 or return to the original position. The driving unit 210 may be connected to a side or bottom surface of the elevation axis 201. The driving unit 210 may be a linear motor or a piston. Alternatively, the driving unit 210 may include a motor and a gear structure that transforms a rotational motion of the motor into a linear motion of the elevation axis 201.

FIG. 5 is a schematic diagram illustrating a pressure controlling unit of the die ejector of FIG. 3.

Referring to FIG. 5, the pressure controlling unit 300 may include the depressurizing unit 303, a gas supplier 304, and an exhausting unit 305.

The hole 110 of the supporting unit 100 may be connected to the pressure controlling unit 300. A main line 311 may be connected to the hole 110. The depressurizing unit 303 may be connected to a depressurizing line 312 that diverges from a first junction of the main line 311. The gas supplier 304 may be connected to a pressurizing line 313 that diverges from a second junction of the main line 311, and the exhausting unit 305 may be connected to an exhausting line 314 that diverges from the second junction. A first three-way valve 301 may be provided at the first junction, and a second three-way valve 302 may be provided at the second junction. The first junction may be located between the hole 110 and the second junction. The first three-way valve 301 and the second three-way valve 302 may be configured to selectively connect the depressurizing line 312 and the pressurizing line 313, respectively, to the main line 311. For example, the first three-way valve 301 or the second three-way valve 302 may each be a solenoid valve.

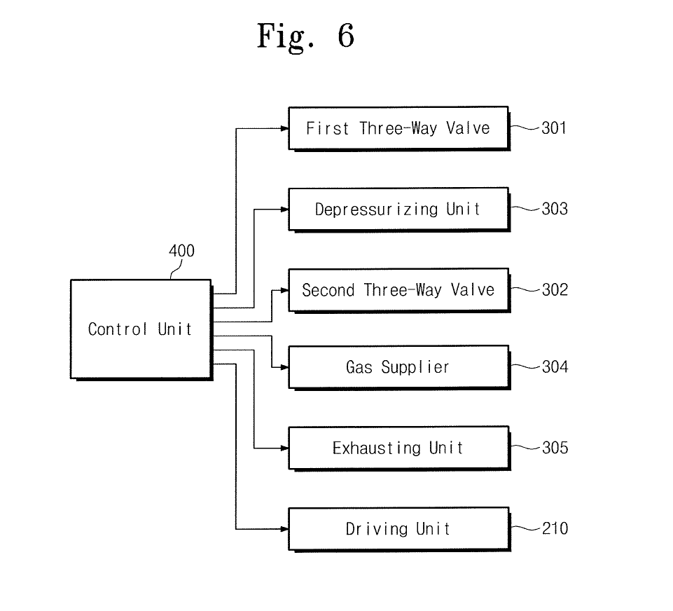

FIG. 6 is a block diagram that illustrates the functions of a control unit.

Referring to FIG. 6, a control unit 400 may be configured to control the first three-way valve 301, the depressurizing unit 303, the second three-way valve 302, the gas supplier 304, the exhausting unit 305, and the driving unit 210.

The control unit 400 may control the first three-way valve 301 so that the depressurizing line 312 can be selectively connected to the main line 311. The first three-way valve 301 may be configured so that gas may flow through a portion connected to the main line 311 in a bi-directional manner. The first three-way valve 301 may be configured so that gas may flow through a portion connected to the depressurizing line 312 in a bi-directional manner. Alternatively, the first three-way valve 301 may be configured so that gas may flow through the first junction toward the depressurizing unit 303 in a uni-directional manner. For example, a portion of the first three-way valve 301 connected to the depressurizing line 312 may be a check valve or a back-pressure preventing valve.

The control unit 400 may control an operation of the depressurizing unit 303. When the depressurizing line 312 is not connected to the main line 311, operation of the depressurizing unit 303 may cease in response to a control signal from the control unit 400. When the depressurizing line 312 is connected to the main line 311, the depressurizing unit 303 may operate in response to a control signal from the control unit 400. The depressurizing unit 303 may exhaust gas from the hole 110 out of the pressure controlling unit 300 via the main line 311 and the depressurizing line 312, thereby decreasing a pressure of the hole 110. When the fixing hole 101 is connected to the depressurizing unit 303, the depressurizing unit 303 may operate when the depressurizing line 312 is connected to the main line 311.

The control unit 400 may control the second three-way valve 302 so that the pressurizing line 313 or the exhausting line 314 can be selectively connected to the main line 311. The control unit 400 may control the first three-way valve 301 and the second three-way valve 302 so that the main line 311 and the pressurizing line 313 are connected to each other. Further, the control unit 400 may control the second three-way valve 302 so that the main line 311 is connected to the exhausting line 314 at the second junction, when the main line 311 is connected to the depressurizing line 312 at the first junction by the operation of the first three-way valve 301.

The control unit 400 may control an operation of the gas supplier 304. When the main line 311 is connected to the exhausting line 314 by operation of the second three-way valve 302, the gas supplier 304 may cease operating in response to a control signal from the control unit 400. When the main line 311 is connected to the pressurizing line 313 by operations of the first and second three-way valves 301 and 302, the gas supplier 304 may operate in response to a control signal from the control unit 400. The gas supplier 304 may operate to supply gas into the hole 110 and thereby increase the pressure of the hole 110. The exhausting unit 305 may operate in response to a control signal from the control unit 400. When the main line 311 is connected to the pressurizing line 313, the exhausting unit 305 may operate in response to a control signal from the control unit 400. When the main line 311 is connected to the depressurizing line 312 at the first junction and to the exhausting line 314 at the second junction, the exhausting unit 305 may operate in response to a control signal from the control unit 400. The exhausting unit 305 may operate to exhaust gas that remains between the first and second junctions or in the exhausting line 314. When the main line 311 is connected to the pressurizing line 313, the control unit 400 may selectively operate the exhausting unit 305. Accordingly, it is possible to exhaust gas that remains in the exhausting line 314. When the main line 311 is connected to the exhausting line 314, the control unit 400 may operate the exhausting unit 305 to exhaust gas that remains in the main line 311 and the exhausting line 314.

In response to a control signal from the control unit 400, the driving unit 210 may reciprocate the elevating unit 200 between the standby and separation positions.

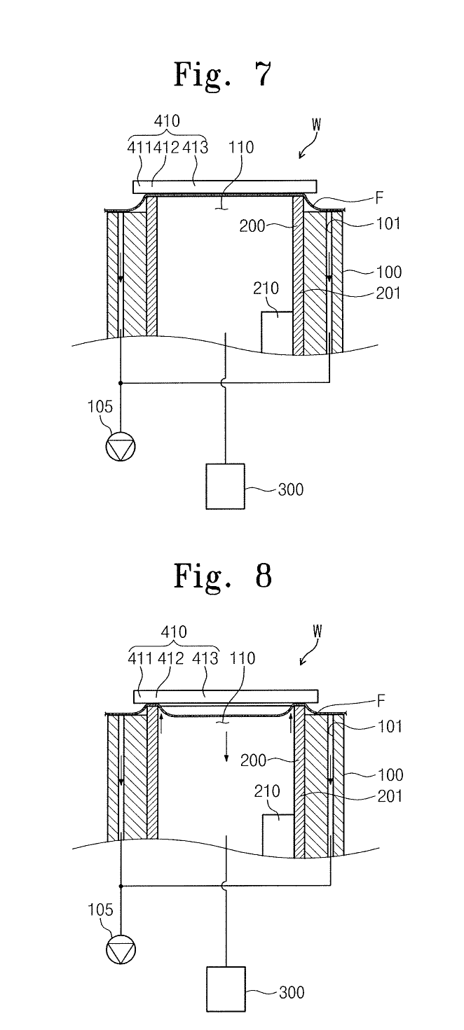

FIG. 7 is a schematic diagram that illustrates how a die is separated from a film by elevating a position of an elevating unit.

A process of separating the die 410 from the film F using the elevating unit 200 will be described with reference to FIGS. 1 through 7.

The delivering robot 42 may unload the wafer W from the cassette C and dispose the unloaded wafer W on the wafer holder 41. The wafer holder 41 may fix the wafer W. The wafer holder 41 may be configured to pull outward the wafer ring disposed along the edge portion of the wafer W, thereby expanding the film F. If the wafer W is fixed by the wafer holder 41, the wafer holder 41 or the die ejector 50 may be moved so that the die 410 is positioned on the die ejector 50. The die ejector 50 may be controlled so that the hole 110 and the elevating unit 200 are positioned below the central region of the die 410. Accordingly, all side surfaces of the die 410 may be positioned on the supporting part 102. If a position of the die 410 is aligned, the depressurizing unit 303 may be operated by the control unit 400 to apply an inhalation pressure to the fixing holes 101 and thereby fix the film F of the wafer W to the supporting unit 100. Hereinafter, a portion of the die 410 supported by the supporting part 102 may be referred to as a first region 411, a portion of the die 410 supported by the elevating unit 200 may be referred to as a second region 412, and a portion of the die 410 located within the elevating unit 200 and exposed by the hole 110 may be referred to as a third region 413.

If the film F is fixed to the supporting unit 100, the driving unit 210 may be controlled by the control unit 400 to elevate the elevating unit 200 to the separation position. If the elevating unit 200 is elevated, the fixing hole 101 may exert a downward force on the film F attached to a bottom surface of the first region 411, thereby separating the film F from the die 410. During separation of the film F from the die 410, the film F may exert a downward force to the first region 411. The force exerted to the die 410 may vary depending on an elevation speed of the elevating unit 200. For example, if the elevation speed of the die 410 increases, the force exerted to the die 410 may increase. In exemplary embodiments, the control unit 400 may control the driving unit 210 so that the elevating unit 200 elevates with a speed that can prevent the die 410 from being broken by the force. When the elevating unit 200 has a shape corresponding to that of the die 410, it is possible to reduce spatial variations in the stress exerted to the first region 411. This may prevent the die 410 from being partially broken while being separated from the film F at the first region 411.

According to exemplary embodiments of the inventive concept, the bottom surface of the die 410 may be supported by a ring shaped elevating unit 200 during elevation thereof. Accordingly, during elevation of the die 410, a force exerted from the elevating unit 200 to the supporting unit 100 may be spatially uniform, regardless of a position of the die 410. Accordingly, it is possible to prevent the die 410 from being broken by a force exerted to a surface that supports the die 410 while elevating the die 410 or by a force exerted to the die 410 while separating the die 410 from the film F.

According to exemplary embodiments of the inventive concept the elevating unit 200 may be a ring. This makes it possible to prevent changes to surfaces of the die 410 and the film F supported by the elevating unit 200 by an operator manipulating the die ejector 50.

FIGS. 8 through 10 are schematic diagrams that illustrate a hole to which an inhalation pressure is applied.

A process of separating the die from the film using an inhalation pressure applied to the hole will be described with reference to FIGS. 8 through 10.

A film F, F1, and F2 attached to first region 411, 421 and 431, second region 412, 422 and 432 and third region 413, 423 and 433 may be separated by a change in pressure of the hole 110. In detail, the pressure controlling unit 300 may depressurize the hole 110. For example, the control unit 400 may control the first three-way valve 301 to connect the main line 311 to the depressurizing line 312, and the control unit 400 may operate the depressurizing unit 303. Gas in the hole 110 may be exhausted by the depressurizing unit 303, and thus, an inhalation pressure may be formed in the hole 110. The film F, F1, and F2 attached to the third region 413, 423, and 433 may be pulled down by the inhalation pressure to separate the film F, F1, and F2 from the die 410, 420, and 430 or weaken an attachment force between the film F, F1, and F2 and the die 410, 420, and 430. During separation of the film F, F1, and F2 from the die 410, 420, and 430, a force from the film F, F1, and F2 or due to the inhalation pressure may be exerted to the third region 413, 423, and 433. The force exerted to the die 410, 420, and 430 may be correspondingly increased by the inhalation pressure applied to the hole 110. If a stress caused by the force increases over a specific strength, the die 410, 420, and 430 may break. In this case, the control unit 400 may control the depressurizing unit 303 so that an inhalation pressure applied to the hole 110 has a strength set to prevent breakage of the die 410, 420, and 430.

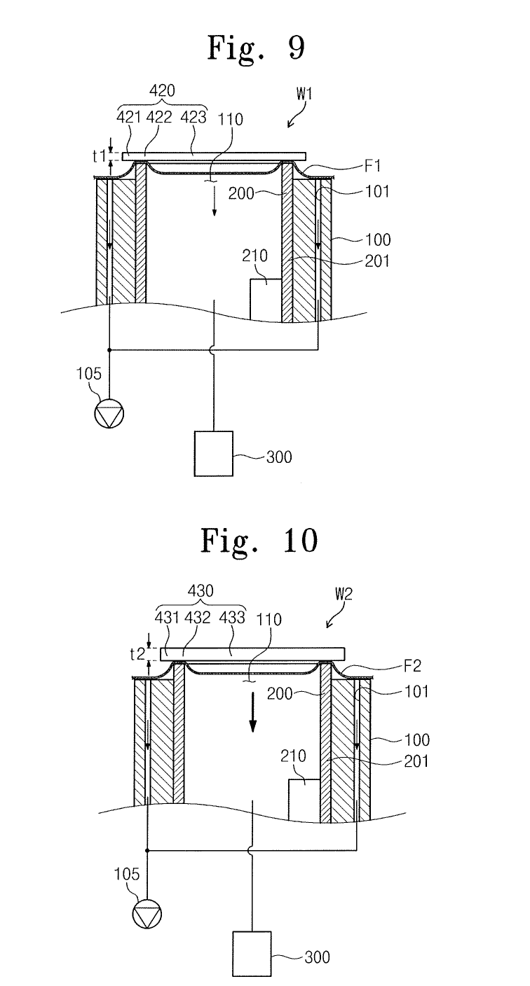

A process of forming the inhalation pressure in the hole 110 may start along with or during elevation of the elevating unit 200, as shown in FIG. 8. In other embodiments, after forming the inhalation pressure in the hole 110, the elevating unit 200 may start to elevate. Alternatively, the process of forming the inhalation pressure in the hole 110 may start after the elevation of the elevating unit 200, as shown in FIGS. 9 and 10.

The control unit 400 may control the depressurizing unit 303 so that the inhalation pressure applied to the hole 110 may differ from case to case. For example, a thickness of the die may differ from wafer to wafer. As shown in FIGS. 9 and 10, a first wafer W1 may include a first die 420 with a thickness t1, while a second wafer W2 may include a second die 430 with a thickness t2 that is greater than the thickness t1. Such variations in thicknesses of the die mean that there is a variation in critical strength of the inhalation pressure that may cause a breakage of the die. Accordingly, the control unit 400 may control the depressurizing unit 303 so that the inhalation pressure applied to the hole 110 differs corresponding to a thickness of the die 410. For example, the control unit 400 may control the depressurizing unit 303 so that the inhalation pressure applied to the hole 110 is lower when the first die 420 is disposed than when the second die 430 is disposed.

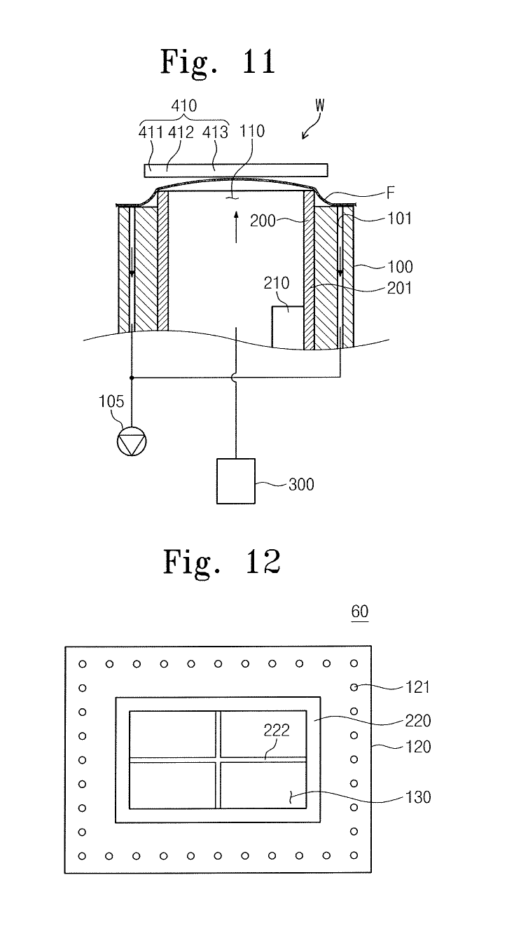

FIG. 11 is a schematic diagram that illustrates a hole to which an injection pressure is applied.

Referring to FIG. 11, under control of the control unit 400, the pressure controlling unit 300 may form the inhalation pressure in the hole 110 for a predetermined duration and then form an injection pressure in the hole 110. For example, under control of the control unit 400, the main line 311 may be connected to the connection line 312 through the first valve 301, and the connection line 312 may be connected to the pressurizing line 313 through the second valve 302. In addition, under control of the control unit 400, the gas supplier 304 may be turned on. Then, gas may be supplied into the hole 110 to form the injection pressure in or on the hole 110.

Since the film F is formed of a flexible material, it can be protruded upward by the injection pressure applied to the hole 110. While protruding, the film F may be separated downward from the die 410 or the film's adhesion to the die 410 may be weakened, over most of the die 410 except for the central portion thereof. When the die 410 separates from the film F, a force from the film F or the injection pressure may be exerted on the die 410. The force exerted on the die 410 may increase due to the injection pressure applied to the hole 110. If a stress caused by the force increases over a specific strength, the die 410 may break. Thus, the control unit 400 may control the gas supplier 304 so that the injection pressure applied to the hole 110 has a strength set to prevent breakage of the die 410.

The control unit 400 may control the gas supplier 304 so that the injection pressure applied to the hole 110 may differ from case to case. For example, similar to the case of the inhalation pressure, the control unit 400 may control the gas supplier 304 so that the injection pressure applied to the hole 110 has different strengths that correspond to a thickness of the die 410. For example, if the thickness of the die 410 decreases, the gas supplier 304 may be configured to apply a reduced injection pressure to the hole 110.

After applying the injection pressure to the hole 110 for a predetermined duration, the bonding head 43 may pick up the die 410 disposed on the die ejector 50 and attach it to the substrate S provided on the working stage 20. Further, the wafer holder 41 or the die ejector 50 may move in a horizontal direction to dispose another die on the wafer holder 41.

While forming the inhalation pressure in the hole 110, under control of the control unit 400, the connection line 312 may be connected to the exhausting line 314 through the second valve 302, and the exhausting unit 305 may be turned on. Then, gas remaining in the connection line 312 or the exhausting line 314 can be exhausted. Further, while pressurizing the hole 110, the exhausting unit 305 may be turned-on by the control unit 400. Then, gas remaining in the exhausting line 314 can be exhausted. In addition, when another die is aligned on the wafer holder 41, under control of the control unit 400, the main line 311 may be connected to the connection line 312 through the first valve 301, and the connection line 312 may be connected to the exhausting line 314 through the second valve 302. In addition, the exhausting unit 305 may be turned on by the control unit 400, thereby exhausting gas remaining in the main line 311, the connection line 312, or the exhausting line 314. If gas remaining in the lines is exhausted, it is possible to prevent the inhalation pressure or an unintentional injection pressure due to the remaining gas.

According to exemplary embodiments of the inventive concept, the second region 412 and the third region 413 of the die 410 may be detached from the film F by the pressure controlling unit 300. The die 410 can be detached from the film F by a process of exhausting or supplying gas from or to the hole 110 through the lines under control of the pressure controlling unit 300. In some embodiments, the separation of the die may be performed by moving a portion of a top surface of the die ejector in a lateral direction. However, this method requires a mechanical movement of the die ejector, and thus takes a long time to separate the die from the film. By contrast, a hydrodynamic method using gas can be performed quicker as compared with the movement of a mechanical component. Accordingly, it is possible to reduce the time taken to separate the die 410 from the film F.

According to exemplary embodiments of the inventive concept, in the process of separating the die 410 from the film F, the die 410 and the film F need not be in contact with a mechanical component. This may prevent damage to or breakage of the die 410 and the film F due to forces applied from mechanical components.

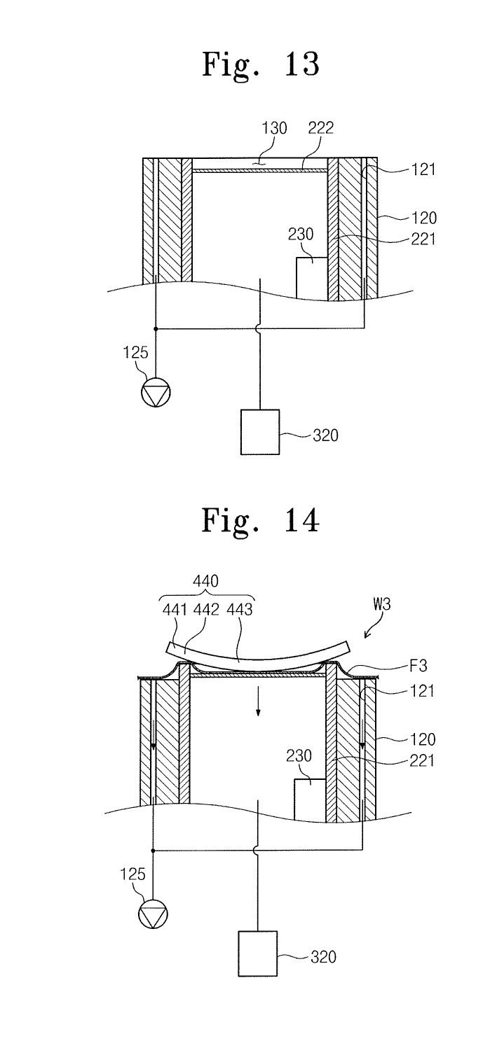

FIG. 12 is a plan view of a die ejector according to other exemplary embodiments of the inventive concept, and FIG. 13 is a side sectional view of the die ejector of FIG. 12.

Referring to FIGS. 12 and 13, a die ejector 60 according to other exemplary embodiments of the inventive concept may include a supporting unit 120 and an elevating unit 220.

The supporting unit 120 includes fixing holes 121, a depressurizing unit 125 connected to the fixing holes 121, a pressure controlling unit 320 connected to a hole 130, and a driving unit 230 connected to a driving part 221 of the elevating unit 220. The die ejector 60 may be configured to have substantially the same features as those in the die ejector 50 described with reference to FIGS. 3 through 5. Thus, for concise description, overlapping description thereto may be omitted.

The elevating unit 220 may be located in the hole 130, which may be disposed in a central region of the supporting unit 120. In a plan view, the elevating unit 220 may have a circular, elliptical, or polygonal ring shape. An outer side surface of the elevating unit 220 may have a shape corresponding to that of the hole 130. For example, the elevating unit 220 may have a side surface that is in contact with or adjacent to an inner side surface of the supporting unit 120. Further, an outer side surface of the elevating unit 220 is contained within the hole 130, and thus, the side surface of the elevating unit 220 may be spaced apart from an inner side surface of the supporting unit 120 by a specific distance. The elevating unit 220 may include a driving part 221 that extends downward from the ring-shaped upper portion.

The elevating unit 220 may include at least one supporting rib 222 that crosses an inner space of the elevating unit 220. If there is one supporting rib 222, the supporting rib 222 may cross a center of the hole 130, in a plan view. In other embodiments, if there are two or more supporting ribs 222, the supporting ribs 222 may be arranged side by side. Alternatively, if there are two or more supporting ribs 222, the supporting ribs 222 may cross each other, thereby forming a mesh structure. A top surface of the supporting rib 222 may be spaced downward from the top surface of the elevating unit 220 by a predetermined distance.

FIG. 14 is a schematic diagram that illustrates how a die is separated from a film by the die ejector of FIG. 12.

A process of separating a die 440 from the film F3 using an inhalation pressure applied to the hole 130 will be described with reference to FIG. 14.

Processes such as aligning the wafer W3 and the die ejector 60, separating a film F3 from a first region 441 by elevating the elevating unit 220, forming the injection pressure along with or after forming the inhalation pressure in the hole 130, separating the die 440 using the bonding head 43, etc., may be performed in substantially the same manner as those described with reference to FIGS. 1 through 7 and 11, and thus, overlapping description thereto may be omitted, for concise description.

In addition, separating the film F3 from the third region 443 using inhalation pressure applied to the hole 130 may be performed in substantially the same manner as that described with reference to FIG. 8.

The supporting rib 222 may limit the distance the film F3 and the die 440 may be pulled from the top surface of the elevating unit 220. The pressure controlling unit 320 may change the inhalation pressure in the hole 130 depending on the situation. For example, if the inhalation pressure goes out of its predetermined range due to, for example, a change in the gas state in a space provided within the die ejector 60, instability of electric power supplied to the pressure controlling unit 320, etc., a downward displacement of the third region 443 of the die 440 may increase. Furthermore, if the predetermined pressure range is set erroneously, the film F3 and the die 440 may be subject to excessive movement that can break the die 440. By contrast, according to exemplary embodiments of the inventive concept, a spacing between the top surfaces of the supporting rib 222 and the elevating unit 220 may be sufficiently small to prevent the die 440 from being broken. Accordingly, the supporting rib 222 may prevent the film F3 and die 440 from being subject to movement that can break the die 440.

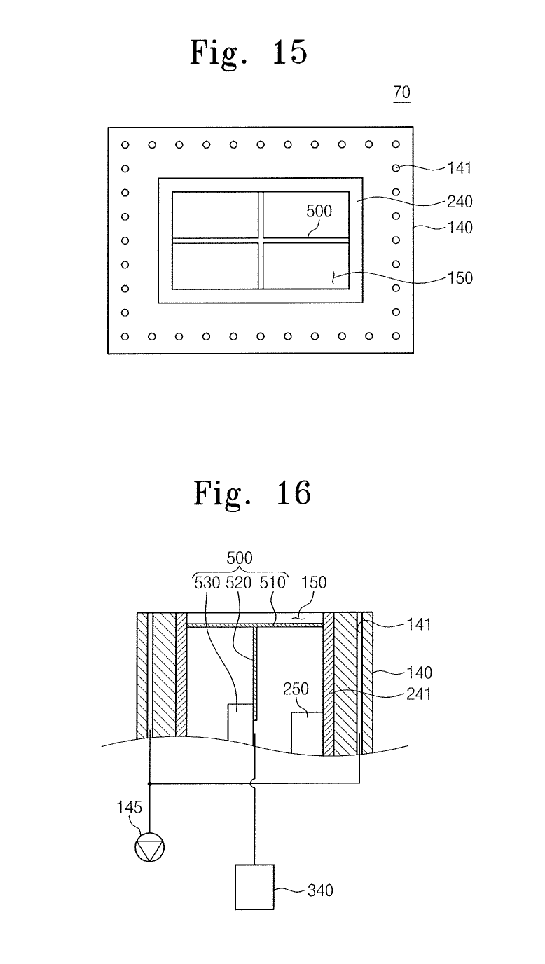

FIG. 15 is a plan view of a die ejector according to still other exemplary embodiments of the inventive concept, and FIG. 16 is a side sectional view of the die ejector of FIG. 15.

Referring to FIGS. 15 and 16, a die ejector 70 according to still other exemplary embodiments of the inventive concept may include a supporting unit 140, an elevating unit 240, and a supplementary elevating unit 500.

The supporting unit 140 includes a fixing hole 141, a depressurizing unit 145 connected to the fixing hole 141, a pressure controlling unit 340 and the elevating unit 240 connected to a hole 150, a driving unit 250 connected to a driving part 241 of the elevating unit 240. The die ejector 70 may be configured to have substantially the same features as those in the die ejector 50 described with reference to FIGS. 3 through 5. Thus, for concise description, overlapping description thereto may be omitted.

The supplementary elevating unit 500 may be provided in a space confined by an inner side surface of the elevating unit 240. The supplementary elevating unit 500 may include a supporting rib 510 and a supplementary elevation axis 520.

At least one supporting rib 510 may be provided to cross the space confined by the inner side surface of the elevating unit 240. A top surface of the supporting rib 510 may be parallel with a top surface of the elevating unit 240 or the supporting unit 140. If there is one supporting rib 510, the supporting rib 510 may cross the center of the hole 150, in a plan view. If there are two or more supporting ribs 510, the supporting ribs 510 may cross each other. For example, a pair of supporting ribs 510 may have a “+”-shaped structure. In other embodiments, a plurality of the supporting ribs 510 may have a mesh-shaped structure.

The supplementary elevation axis 520 may extend downward from a bottom surface of the supporting rib 510. A supplementary driving unit 530 may be connected to the supplementary elevation axis 520. The supplementary driving unit 530 may be configured to move the supporting rib 510 higher than the supporting unit 140 or back to the original position of the supporting rib 510, using the supplementary elevation axis 520. The supplementary driving unit 530 may be connected to a side or bottom surface of the supplementary elevation axis 520. The supplementary driving unit 530 may be a linear motor or a piston. Alternatively, the supplementary driving unit 530 may include a motor and a gear structure that can transform a rotational motion of the motor into a linear motion of the driving part 241.

If the elevating unit 240 is elevated, the supplementary elevating unit 500 may also be elevated. By operating the supplementary elevating unit 500, the top surface of the supporting rib 510 may be elevated above the top surface of the elevating unit 240 by a predetermined distance. To form inhalation pressure during elevation of the elevating unit 240, the supplementary elevating unit 500 and the elevating unit 240 may be elevated together while maintaining the predetermined distance therebetween. To form inhalation pressure after elevating the elevating unit 240, the supplementary elevating unit 500 and the elevating unit 240 may be elevated together or sequentially with a temporal interval. Since the supporting rib 510 may be spaced apart from the top surface of the elevating unit 240 by the predetermined distance while forming the inhalation pressure, it is possible to prevent breakage of the die due to the inhalation pressure, as described with reference to FIG. 12.

The inhalation pressure needed to break a die may vary depending on a thickness of the die. Furthermore, a magnitude of a third region displacement that can break a die may vary depending on a thickness of the die. Thus, the predetermined distance between the top surfaces of the elevating unit 240 and the supplementary elevating unit 500 may be set based on the thickness of the die.

According to exemplary embodiments of the inventive concept, a die can be safely separated from a film.

While exemplary embodiments of the inventive concepts have been particularly shown and described, it will be understood by one of ordinary skill in the art that variations in form and detail may be made therein without departing from the spirit and scope of the attached claims.

1. A die ejector, comprising:
a supporting unit configured to support a bottom surface of a film on which a die is attached, wherein the supporting unit has a hole disposed at a center thereof;
an elevating unit in the hole and configured to move along a vertical direction, wherein the elevating unit has a ring-shaped structure;
a driving unit connected to the elevating unit and configured to move the elevating unit along the vertical direction; and
a pressure controlling unit connected to the hole and configured to control a pressure of the hole.

2. The die ejector of claim 1, wherein the elevating unit has a shape corresponding to that of the die.

3. The die ejector of claim 1, wherein an area of a top surface of the elevating unit is is smaller than that of a bottom surface of the die.

4. The die ejector of claim 1, further comprising a control unit configured to control the driving unit and the pressure controlling unit,
wherein the control unit controls the pressure controlling unit to apply an inhalation pressure to the hole to separate the film from the die.

5. The die ejector of claim 4, wherein, after the film is separated from the die, the control unit controls the pressure controlling unit to supply gas into the hole to apply an injection pressure to the hole.

6. The die ejector of claim 4, further comprising:
a supplementary elevating unit disposed in a space delimited by an inner side surface of the elevating unit; and
a supplementary driving unit connected to the supplementary elevating unit and configured to provide power to vertically drive the supplementary elevating unit.

7. The die ejector of claim 6, wherein the control unit controls the supplementary elevating unit wherein a top surface of the supplementary elevating unit is spaced below a top surface of the elevating unit while forming the inhalation pressure in the hole.

8. The die ejector of claim 1, further comprising a supporting rib that crosses a space in the elevating unit.

9. The die ejector of claim 8, wherein the supporting rib has a top surface that is spaced downward from a top surface of the elevating unit by a predetermined distance.

10. The die ejector of claim 1, wherein the pressure controlling unit comprises:
a main line connected to the hole;
a depressurizing line diverging from a first junction of the main line; and
a pressurizing line diverging from a second junction of the main line,
wherein the first junction is disposed between the hole and the second junction.

11-15. (canceled)

16. A die ejector, comprising:
a supporting unit configured to support a bottom surface of a film on which a die is attached, wherein the supporting unit has a hole disposed at a center thereof;
a ring shaped elevating unit contained within in the hole and configured to move along a vertical direction; and
a pressure controlling unit connected to the hole, wherein the pressure controlling unit is configured to apply an inhalation pressure to the hole to separate the film from the die, and to supply gas into the hole to apply an injection pressure to the hole after the film is separated from the die.

17. The die ejector of claim 16, further comprising:
a driving unit connected to the elevating unit and configured to elevate the elevating unit along a vertical direction during application of the inhalation pressure to the hole, and to return the elevating unit to a standby position after separating the die from the film; and
a control unit configured to control the driving unit and the pressure controlling unit.

18. The die ejector of claim 16, wherein the supporting unit further comprises a plurality of fixing holes disposed on an outer portion thereof that are connected to a depressurizing unit, said fixing holes being configured to fix said film during application of the inhalation pressure to the hole.

19. The die ejector of claim 16, wherein the pressure controlling unit comprises:
a main line connected to the hole;
a depressurizing unit connected to a depressurizing line that diverges from a first three-way valve of the main line;
a gas supplier connected to a pressurizing line that diverges from a second three-way valve of the main line; and
an exhausting unit connected to an exhausting line that diverges from the three-way valve,
wherein the first three-way valve and the second three-way valve may be configured to selectively connect the depressurizing line and the pressurizing line, respectively, to the main line.

20. The die ejector of claim 17, further comprising:
a supplementary elevating unit disposed in a space delimited by an inner side surface of the elevating unit; and
a supplementary driving unit connected to the supplementary elevating unit and configured to provide power to vertically drive the supplementary elevating unit,
wherein the control unit controls the supplementary elevating unit wherein a top surface of the supplementary elevating unit is spaced below a top surface of the elevating unit while forming the inhalation pressure in the hole.
